(19) United States
(12) Patent Application Publication
(10) Pub. No.: US 2025/0011166 A1
(43) Pub. Date: Jan. 9, 2025

(54) ADDITIVE MANUFACTURING USING BONDING OF VOXELS AND RELATED SYSTEMS, DEVICES, AND ARTICLES

(71) Applicant: Massachusetts Institute of Technology, Cambridge, MA (US)

(72) Inventors: Alain Stefan Reiser, Cambridge, MA (US); Christopher A. Schuh, Wayland, MA (US)

(73) Assignee: Massachusetts Institute of Technology, Cambridge, MA (US)

(21) Appl. No.: 18/654,474

(22) Filed: May 3, 2024

Related U.S. Application Data
(60) Provisional application No. 63/511,823, filed on Jul. 3, 2023.

(51) Int. Cl. B81C 1/00; B33Y 10/00; B33Y 70/00

(52) U.S. Cl. CPC B81C 1/00373; B33Y 10/00; B33Y 70/00

(57) ABSTRACT

Additive manufacturing using bonding of voxels and related systems, devices, and articles are generally described. Certain embodiments are related to additive manufacturing with microscale resolution using solid-state kinetic bonding of microparticles or microfabricated thin-film voxels.

### RELATED APPLICATIONS

This application claims priority under 35 U.S.C. § 119(e) to U.S. Provisional Patent Application No. 63/511,823, filed Jul. 3, 2023, and entitled “Additive Manufacturing with Microscale Resolution using Solid-State Kinetic Bonding of Sequentially Transferred Microparticles or Microfabricated Thin-Film Voxels,” which is incorporated herein by reference in its entirety for all purposes.

### GOVERNMENT SPONSORSHIP

This invention was made with government support under grant number DE-SC001809 awarded by United States Department of Energy. The Government has certain rights in the invention.

### TECHNICAL FIELD

Additive manufacturing using bonding of voxels and related systems, devices, and articles are generally described.

### SUMMARY

This Summary introduces a selection of concepts in simplified form that are described further below in the Detailed Description. This Summary neither identifies key or essential features, nor limits the scope, of the claimed subject matter.

Additive manufacturing using bonding of voxels and related systems, devices, and articles are generally described. Certain embodiments are related to additive manufacturing with microscale resolution using solid-state kinetic bonding of microparticles or microfabricated thin-film voxels. The subject matter of the present disclosure involves, in some cases, interrelated products, alternative solutions to a particular problem, and/or a plurality of different uses of one or more systems and/or articles.

Certain aspects are related to methods, such as methods of additive manufacturing.

In some embodiments, a method of additive manufacturing comprises a. providing a substrate; b. providing a first voxel and a second voxel; c. accelerating the first voxel into the substrate to induce bonding of the first voxel to the substrate; and d. accelerating the second voxel toward the substrate to induce bonding of the second voxel to the first voxel.

In certain embodiments, a method comprises a. providing a substrate; b. providing a microparticle or microfabricated thin film (a voxel); and c. accelerating the voxel into the substrate to induce solid-state bonding of the voxel to the substrate.

Methods comprise, in some embodiments, a. providing a substrate; b. providing a thin film; and c. accelerating the thin film toward the substrate to induce bonding of the thin film to the substrate.

In accordance with some embodiments, a method comprises a. providing a first substrate, a second substrate, a voxel in contact with the second substrate, and a sacrificial layer between the first and second substrates; and b. ablating the sacrificial layer such that the voxel is accelerated from the second substrate to a third substrate such that the voxel bonds to the third substrate.

In certain embodiments, a method comprises a. providing a substrate; b. providing a microparticle or microfabricated thin film (a voxel); and c. ablating and accelerating the voxel into the substrate by a laser, wherein the laser induces solid-state bonding of the voxel to the metal substrate.

One aspect of the disclosure herein is a method comprising: a. providing a substrate; b. providing a microparticle or microfabricated thin film (a voxel); and c. ablating and accelerating the voxel into the substrate by a laser, wherein the laser induces solid-state bonding of the voxel to the metal substrate.

In one embodiment of the disclosed methods, neither the voxel nor the substrate is heated by the laser. In one embodiment of the disclosed methods, the substrate comprises an inorganic material. In one embodiment of the disclosed methods, the substrate comprises glass. In one embodiment of the disclosed methods, the voxel comprises an inorganic material. In one embodiment of the disclosed methods, the voxel comprises a metal. In one embodiment of the disclosed methods, voxel comprises gold metal (Au). In one embodiment of the disclosed methods, c is repeated to stack the voxels and produce a 3D structure. In one embodiment of the disclosed methods, a metal coating is produced on the substrate. In one embodiment of the disclosed methods, a 100 nm metal coating is produced on the substrate. In one embodiment of the disclosed methods, 6-10 voxels are stacked on the substrate. In one embodiment of the disclosed methods, a stack of several cubic millimeters is produced on the substrate.

Other advantages and novel features of the present disclosure will become apparent from the following detailed description of various non-limiting embodiments of the disclosure when considered in conjunction with the accompanying figures. In cases where the present specification and a document incorporated by reference include conflicting and/or inconsistent disclosure, the present specification shall control.

### BRIEF DESCRIPTION OF THE DRAWINGS

Non-limiting embodiments of the present disclosure will be described by way of example with reference to the accompanying figures, which are schematic and are not intended to be drawn to scale unless otherwise indicated. In the figures, each identical or nearly identical component illustrated is typically represented by a single numeral. For purposes of clarity, not every component is labeled in every figure, nor is every component of each embodiment of the disclosure shown where illustration is not necessary to allow those of ordinary skill in the art to understand the disclosure. In the figures:

FIG. 1 shows launch of microparticles as described in Hassani-Gangaraj, et al.

FIGS. 2A-2C show, in accordance with certain embodiments, laser-induced additive assembly of metal thin films by impact-induced solid-state bonding. FIG. 2A shows the launch principle. FIG. 2B shows the launch pad used for the transfer of thin film voxels. FIG. 2C shows experimental images corresponding to the schematic illustration of FIG. 2B.

FIG. 3 provides proof of concept for additive manufacturing (AM) using microfabricated voxels, in accordance with certain embodiments. Inset a) shows microfabricated Au thin-film voxels on the launch pad. During launch by laser ablation of a sacrificial layer, they are shielded from the ablation event. Inset b) shows that, upon impact, metal voxels of different sizes and shape (letters “N1”, third panel), can be bonded (≈400 m s⁻¹). Inset c) shows a stack of six Au voxels. Inset d) shows that, in preliminary experiments, almost full density was achieved (cross-section). Inset e) shows that the bond between voxels can be continuous. Inset f) shows alternative approaches, e.g., ink transfer, deposit metals of much lower density (here, sintered Ag ink⁵).

FIG. 4 provides proof of concept for AM with microparticles. The left inset shows a stack of approx. 20 Au particles approx. 15-20 μm in diameter. The right inset shows a 3D scan of the deposited structure (ca 30 μm in diameter and 50 μm in height). The build size was limited by the manual transfer of individual particles. Automation of particle transfer would build on established automation technology and could enable build sizes of cubic millimeters.

FIG. 5 demonstrates that established small-scale AM methods for direct deposition of inorganic materials face challenges of materials quality and range. Methods based on transfer of inks or melts offer insufficient materials quality. Methods based on the synthesis of metals face challenges accessing the broad range of materials needed for many applications.

FIG. 6 shows micrographs depicting damage of the launch pad, according to some embodiments.

FIGS. 7A-7B show micrograph sequences over time of the launch of a SiO₂ particle, according to some embodiments.

FIGS. 8A-8C illustrate the spatial precision of impact between previous methods (A) and the methods described herein (B-C), according to some embodiments.

FIGS. 9A-9B show micrograph sequences over time of the launch of particles at different temperatures using a previous launchpad (A) and a launchpad as described herein (B).

FIG. 10A shows a micrograph sequence over time of the launch of a particle, according to some embodiments.

FIG. 10B shows laser scanning optical micrographs, height maps, and depth profiles of indentions in a substrate from a thin disk impact.

FIGS. 11A-11B are plots comparing the launch efficiency between previous launch pads and the launch pads described herein, according to some embodiments.

FIGS. 12A-12B are micrographs showing additively manufactured structures made from voxels, according to some embodiments.

FIG. 12C shows micrographs of various sized voxels, according to some embodiments.

FIG. 12D is a micrograph showing an array of voxels that was additively manufactured in parallel, according to some embodiments.

### DETAILED DESCRIPTION

The following Detailed Description references the accompanying drawings which form a part of this application, and which show, by way of illustration, specific example implementations. Other implementations may be made without departing from the scope of the disclosure. Reference numbers in superscripts herein refer to the corresponding literature listed in the attached References which forms a part of this Specification, and the literature is incorporated by reference herein.

Disclosed herein are methods for high-resolution additive manufacturing (AM) of metals (and possibly polymers as well as polymer- or metal-matrix composites). The methods are, in accordance with certain embodiments, based on the laser-induced transfer of individual voxels (microparticles or microfabricated thin films) and their bonding in the solid state upon impact at high velocities. A resolution on the order of 1-10 μm (two orders of magnitude better than established metal-AM processes) can be achieved. Compared to extant processes for AM of metals with micro- and nanoscale resolution, the approaches described herein offer a unique combination of 1) high density (generally associated with good performance of materials) and 2) a wide range of accessible materials. Furthermore, in principle the chemistry of individual particles could be controlled and multi-material AM with single-particle resolution can be imagined. The method was demonstrated for sequential and parallel transfer.

Voxel is a term that generally refers to microparticles or thin films. In some embodiments, the microparticles or thin films are microfabricated. According to some embodiments, the average largest maximum dimension of a voxel used herein is less than or equal to 1 mm, less than or equal to 900 microns, less than or equal to 800 microns, less than or equal to 700 microns, less than or equal to 600 microns, less than or equal to 500 microns, less than or equal to 400 microns, less than or equal to 300 microns, less than or equal to 200 microns, less than or equal to 100 microns, less than or equal to 50 microns, or less than or equal to 10 microns. In some embodiments, it may be desirable to use larger voxels (e.g., voxels having maximum dimensions of at least 10 microns, at least 100 microns, at least 500 microns, or larger), as any additive manufacturing using such voxels may be accordingly sped up. Alternatively, while using smaller voxels may slow any additive manufacturing, it would provide a correspondingly higher resolution.

The voxel may be made of any of a variety of suitable materials, in some embodiments. For example, in certain embodiments, the voxel comprises an inorganic material. In some embodiments, the voxel comprises a metal. In some embodiments, the voxel comprises gold (Au) metal. In some embodiments, the voxel comprises Au, platinum (Pt), silver (Ag), copper (Cu), nickel (Ni), iron (Fe), cobalt (Co), aluminum (Al), titanium (Ti), and/or alloys thereof. In certain embodiments, the voxel may be microfabricated, as described elsewhere herein, and thus the voxel may comprise any of a variety of materials that may be microfabricated through known methods (e.g., lithographic methods). In some embodiments, the voxels may comprise various polymers.

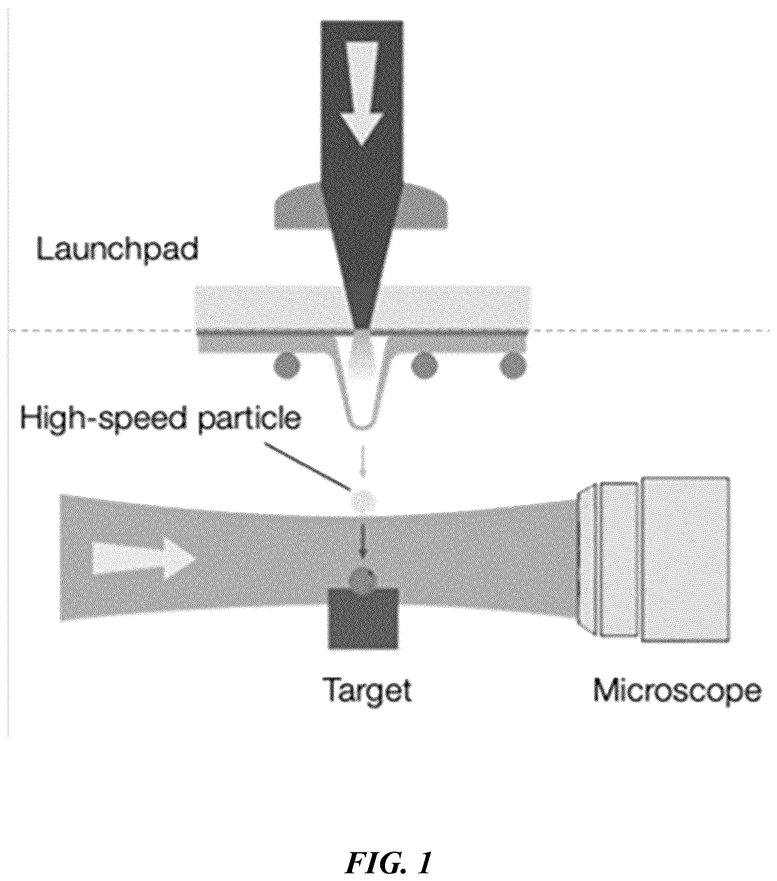

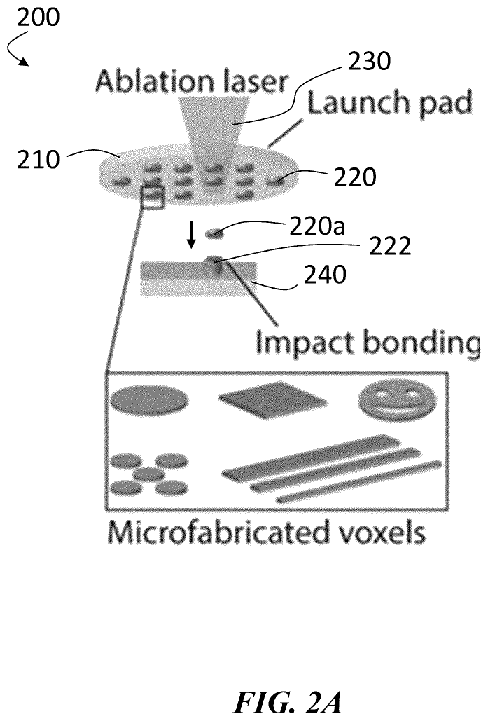

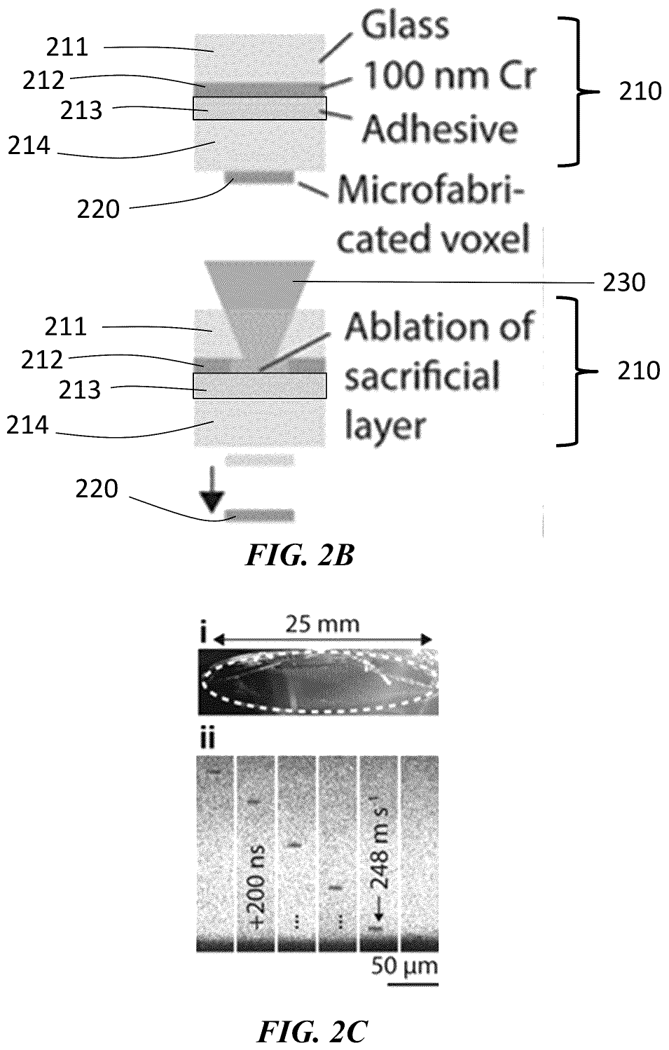

The invented technology uses, in accordance with certain embodiments, laser-induced ablation of a sacrificial film to accelerate individual particles or voxels towards a substrate (FIGS. 1 and 2A-2C). Aspects of the laser launch principle have been disclosed both for particles^{1,2} and thin films³.

Previously, the launch principles have been explored using microparticles on a substrate comprising three layers, as shown in FIG. 1. The three layers include a glass layer, a gold film over the glass layer, and an elastomeric polyurea film (PU) over the gold layer. The microparticles are positioned in contact with the PU layer. Upon irradiation with a laser, the gold layer is ablated and results in rapid expansion of the PU layer, launching the microparticle therefrom. Such previous launch systems were used to individually launch particles and measure the corresponding ballistic parameters. In other prior systems, rather than a three-layered structure, a two layered structure is used. The two layered structure comprises a glass layer and a laser-absorbing polymer layer. The laser-absorbing polymer layer functions similarly to the gold and PU layers of the three-layered system. In other prior systems, a two layered structure comprising a glass layer and a gold layer have been used.

Ablation generally refers to the removal of something from an object. In some embodiments, a sacrificial layer may be ablated, which may expand a polymeric layer adjacent to the sacrificial layer and/or move a substrate comprising glass adjacent to the sacrificial layer. Expansion of a polymeric layer and/or movement of a substrate comprising glass may accelerate a voxel on the polymeric layer of the substrate comprising glass toward a target or substrate, where the impact between the voxel and the target or substrate may result in a chemical bond (e.g., a solid state bond) between the voxel and the target or substrate. This process of the laser indirectly accelerating the voxel and thereby forming a bond between the voxel and the target or substrate may generally be referred to as “laser-induced bonding.” Other methods for propelling the voxel (e.g., via chemical propellants) can also be used. Other methods for ablating, e.g., ablating a sacrificial layer, are also possible.

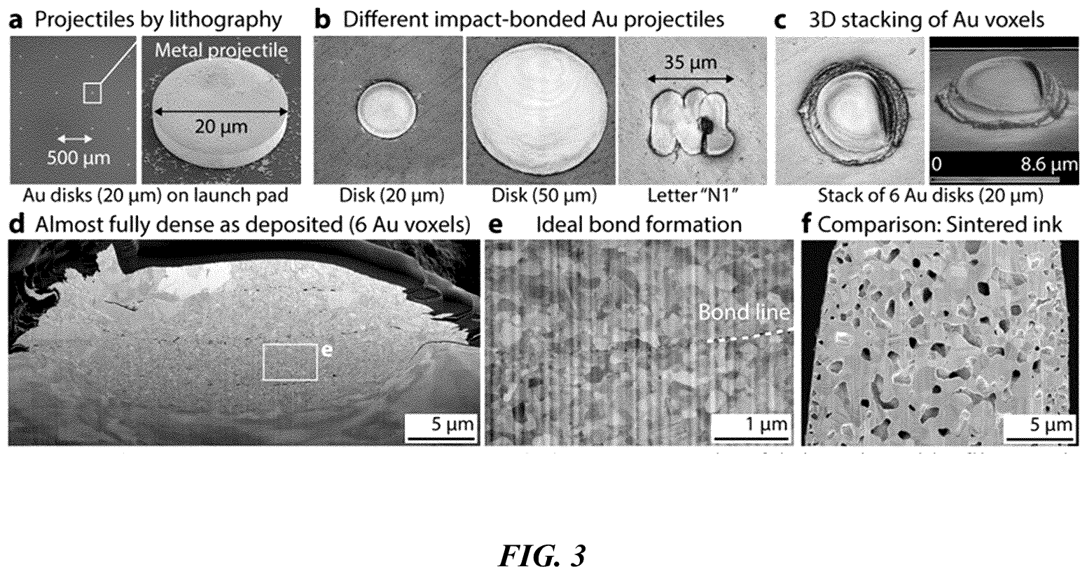

In accordance with certain embodiments, the accelerated particles are neither heated by the laser nor otherwise affected by the ablation. If accelerated to sufficient velocities, in accordance with some embodiments, particles and thin films bond to a metallic substrate. For example, in some embodiments, voxels can be bonded to produce metal coatings on a substrate. In some embodiments, voxels can be bonded to produce metal coatings on a metallic substrate. In some embodiments, accelerating a voxel toward an inorganic substrate such as glass may facilitate adhesion between the voxel and the substrate, e.g., depending on a smoothness of an exposed surface of the substrate into which the voxel is accelerated. In some embodiments, the metal coating may be as thin as 100 nm on inorganic materials such as glass. In some embodiments, the thickness of the metal coating may be greater than or equal to 10 nm, greater than or equal to 100 nm, greater than or equal to 1 micron, greater than or equal to 5 microns, greater than or equal to 10 microns, greater than or equal to 25 microns, greater than or equal to 50 microns, greater than or equal to 100 microns, greater than or equal to 200 microns, greater than or equal to 300 microns, or greater than or equal to 400 microns. In some embodiments, the thickness of the metal coating may be less than or equal to 500 microns, less than or equal to 400 microns, less than or equal to 300 microns, less than or equal to 200 microns, less than or equal to 100 microns, less than or equal to 50 microns, less than or equal to 25 microns, less than or equal to 10 microns, less than or equal to 5 microns, or less than or equal to 1 micron. According to some embodiments, the thickness of the metal coating produced on the substrate may be related to the thickness of the voxels used to form the metal coating. In some embodiments, a voxel may be accelerated into a substrate including a thin film comprising a metal. For example, in some embodiments, the substrate may comprise glass and a metallic thin film on a surface of the glass. In some such cases, the voxel may bond to the metallic thin film of the substrate. When using thin films, in accordance with certain embodiments, voxels can be shaped by lithography on the launch pad and complete layers instead of individual voxels can be transferred. As one example, the letters “N1” in FIG. 3 can be transferred as complete layers. Additionally, the “N1” in FIG. 3 demonstrates the result of accelerating multiple voxels in parallel towards a substrate (i.e., the “N” and the “1”). Accordingly, in certain embodiments, multiple voxels may be prefabricated on a substrate (e.g., a launch pad) as described in more detail elsewhere herein and then accelerated in parallel towards a substrate. Parallel acceleration of multiple voxels may be facilitated, in some embodiments, by using a single laser having a large enough cross-sectional dimension to ablate a sacrificial film adjacent to each voxel configured to be transferred in parallel. In some embodiments, multiple lasers may be used simultaneously to accelerate multiple voxels in parallel. Parallel transfer, according to some embodiments, may desirably increase resolution of a resulting structure as the structure may be prefabricated via typical microfabrication methods.

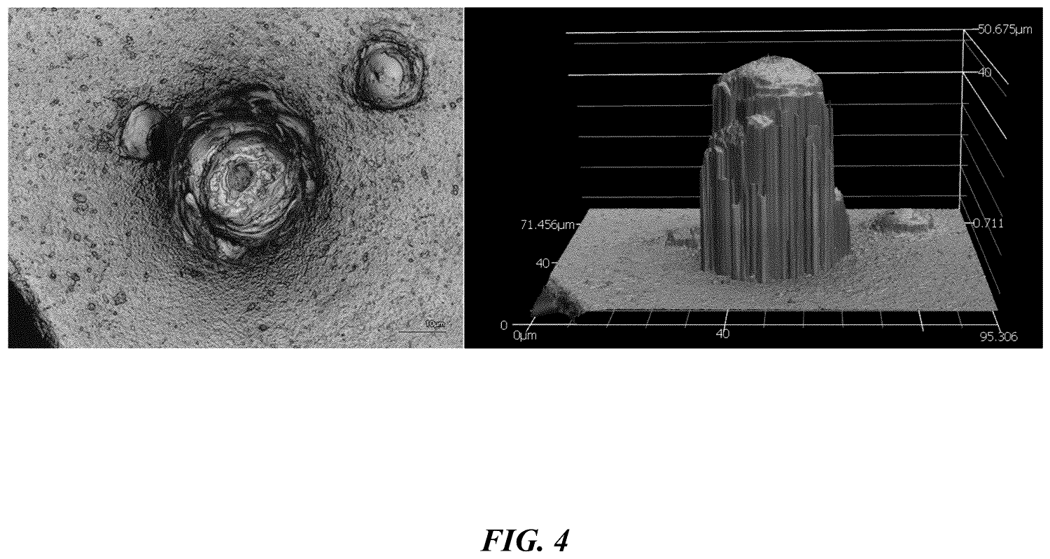

In accordance with certain embodiments, both thin films and particles can be stacked to build up material. Stacks of multiple Au voxels prove the concept for AM (See FIG. 3). Deposited Au was almost fully dense and of much lower porosity than metals from ink-based small-scale AM (compare (e) and (f) in FIG. 3). The bond between voxels can be almost free of porosity (see (e) in FIG. 3). Similarly, particles can be stacked to 3D structures (FIG. 4). In some embodiments, the particles may be stacked into a 3D structure by repeatedly ablating and accelerating a voxel into a substrate by a laser, wherein the laser induces bonding (e.g., solid-state bonding) of the voxel to the metal substrate. However, when performed with a second voxel the laser may induce bonding between the second voxel and a first voxel already present on the substrate, in some embodiments. This may be further repeated with a third voxel, a fourth voxel, and so forth, in accordance with some embodiments. In some embodiments, 6 to 10 voxels may be stacked on the substrate. In some embodiments, greater than or equal to 6 voxels, greater than or equal to 10 voxels, greater than or equal to 50 voxels, greater than or equal to 100 voxels, or greater than or equal to 1,000 voxels, and/or up to 10⁴ voxels, up to 10⁵ voxels, up to 10⁶ voxels, up to 10⁷ voxels, up to 108 voxels, or up to 10⁹ voxels, or more voxels may be stacked. According to some embodiments, following stacking several voxels on a substrate, the stack may have a volume comprising several cubic millimeters (e.g., greater than or equal to 1 mm³, greater than or equal to 2 mm³, greater than or equal to 3 mm³, greater than or equal to 5 mm³, greater than or equal to 10 mm³, greater than or equal to 50 mm³, and/or up to 100 mm³, up to 500 mm³, up to 1 cm², or more).

Disclosed herein, in accordance with some embodiments, is the use of solid-state bonding upon high-velocity impact, applicable to particles and thin film voxels, for microscale additive manufacturing.

Referring again to FIG. 2A, this schematic illustration depicts a system 200 including a launch pad 210 on which multiple voxels 220 (e.g., a first voxel, a second voxel, etc.) are positioned. A laser 230 may be directed toward a first voxel 220a, thereby accelerating it toward a substrate 240. As depicted, the first voxel 220a may be directed towards other voxels 222 already present on the substrate 240 in the direction shown by the arrow to induce bonding between the first voxel 220a and the other voxels 222. The embodiment depicted in FIG. 2A is non-limiting, and other embodiments are further contemplated herein. For example, as illustrated in FIG. 2A, the voxels may be microfabricated (e.g., as shown in the inset of FIG. 2A) and have any of a variety of suitable shapes, in some embodiments.

FIG. 2B shows a schematic illustration of an example launch pad 210. Here, the launch pad includes a first substrate 211, a sacrificial layer 212, an adhesive 213, and a second substrate 214. In some embodiments, first substrate 211 and/or second substrate 214 is made of glass. Other materials are also possible. A microfabricated voxel 220 in the form of a thin disk is positioned on second substrate 214. As shown in the bottom portion of FIG. 2B, upon ablation of the sacrificial layer 212 by a laser 230, the microfabricated voxel 220 is launched from the second substrate 214 of the launch pad 210, in the direction of the arrow shown in FIG. 2B. FIG. 2C includes experimental images showing the launching of a voxel from a substrate as a function of time.

Some aspects of the present disclosure are related to methods, for example, methods performed using the systems shown in FIGS. 2A-2B. For instance, in some embodiments, the methods described herein are for additive manufacturing. In some embodiments, the method includes providing a substrate (e.g., a first substrate, a launch pad). The method may further include providing a first voxel and optionally a second voxel. In some such embodiments, the first voxel and second voxel, when present, may be present on a substrate, e.g., a launch pad. The first and second voxel may be preformed in certain shapes on the substrate, according to some embodiments. In some embodiments, the voxels may be preformed via microfabrication. In some embodiments, one or more of the voxels may then be accelerated toward a substrate (e.g., sequentially and/or in parallel). In some embodiments, methods described herein may comprise preforming or shaping a first voxel prior to accelerating the first voxel into the substrate. A non-limiting example is shown in FIG. 2B. Here, the launch pad may include a first substrate, a second substrate comprising glass, a sacrificial layer between the first and second substrates, and a voxel in contact with the second substrate comprising glass. In some embodiments, the launch pad may further include an adhesive layer, e.g., for adhering the second substrate comprising glass to the sacrificial layer. The method may include ablating the sacrificial layer such that the voxel is accelerated from the second substrate to a third substrate such that the voxel bonds to the third substrate. The third substrate may be a target, in some embodiments. In some embodiments, the method includes ablating the sacrificial layer such that the voxel is accelerated from the second substrate to a third substrate such that the voxel adheres to the third substrate. Any of a variety of suitable materials are possible for the substrate (e.g., the target), in some embodiments. In some embodiments, the substrate comprises an inorganic material. In some embodiments, the substrate comprises glass. In some embodiments, the substrate comprises a ceramic and/or a metal such Al, Au, Cu, Ag, Fe, etc. In some embodiments, the substrate comprises a thin film of any suitable material, coated onto a fourth substrate made of any suitable material. For example, in some embodiments, the substrate comprises glass having a thin film comprising metal thereon.

In some embodiments, the methods described herein may comprise accelerating the voxel toward the substrate to induce solid-state bonding of the voxel to the substrate (e.g., a metal substrate). In some embodiments, the method includes accelerating the thin film toward the substrate to induce bonding of the thin film to the substrate. In some embodiments, the method may further comprise ablating a sacrificial layer, thereby accelerating the voxel. According to some embodiments, the accelerating of the voxel toward the substrate may result in an impact between the voxel and the substrate, which may induce solid state bonding between the voxel and the substrate.

As noted above, certain previous methods utilizing laser-induced launching were limited to particles due to the polymeric layer that expanded and facilitated the launch of the particles. Unexpectedly, the presence of the second substrate comprising glass (e.g., element 214 in FIG. 2B) of the launch pad in contact with voxels maintains the ability to launch a voxel from the launch pad, despite the absence of the polymeric layer designed to expand and launch the particles of previous systems. This advantageously provides the ability to microfabricate voxels onto a surface of the second substrate comprising glass using, for example, standard lithographic methods. Accordingly, voxels of a variety of materials may be microfabricated in any of a variety of shapes that are attainable via known microfabrication techniques. The additive manufacturing methods described herein, thus, may launch voxels having specific shapes that could not be launched via known methods (e.g., a smiley face as shown in FIG. 2A).

The embodiments described herein can exhibit one or more of a number of advantages and improvements over previous methods.

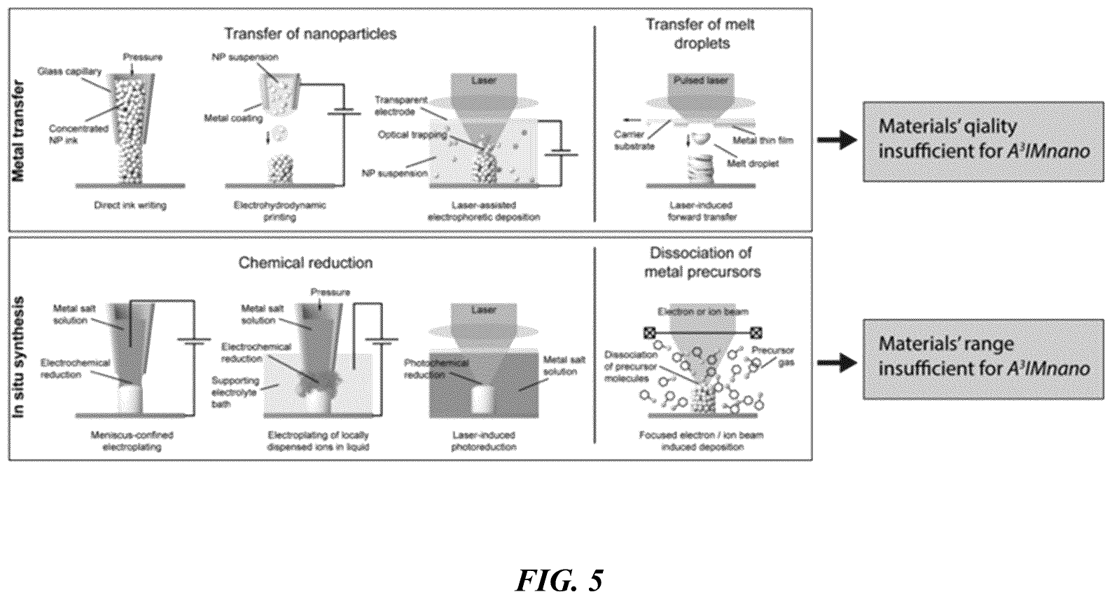

A number of microscale AM techniques with a minimum feature size of <10 μm were developed in the past decade⁶ (see, e.g., FIG. 5). These techniques generally target the fabrication of complex three-dimensional structures with feature sizes in the micro- and submicrometer range, for microelectromechanical systems, 3D electronics, or devices for energy storage. For inorganic materials, many small-scale AM methods use colloidal inks, e.g., direct ink writing (DIW)⁷, electrohydrodynamic printing⁸ and laser-induced forward transfer (LIFT)⁹. Other techniques synthesize the material upon printing, like focused electron-beam-induced deposition¹⁰ (FEBID), and electrochemical methods^{11, 12-18}.

Shown and anticipated advantages of the disclosed method include the following:

The kinetic, solid-state bonding, in accordance with certain embodiments, combines two advantages that existing technologies cannot combine. First, access to an extremely wide range of materials and metals. The kinetic bonding has been demonstrated at the macroscale by processes like cold spray or explosion welding for all common engineering metals and also the fabrication of metal-organic or metal-inorganic composites. This is in stark contrast to ink-based AM methods (currently most widespread in research) that are mainly limited to noble metal inks.

A high density of deposited materials was shown, in accordance with certain embodiments. Accompanying high materials performance are thus expected (e.g., high mechanical properties or electrical conductivity are expected). This outperforms the materials fabricated by ink-based methods.

The methods, in accordance with some embodiments, have unique prospects for multi-metal and multi-material synthesis. This area is clearly identified as a future manufacturing thrust that will provide for functional, printed devices and advanced heterostructured composite materials fabricated by AM and structured across length scales for best performance in a broad range of applications (for example permanent magnets, structural metals, protective coatings, or electrodes for batteries or fuel cells). The solid-state, impact-induced bonding principle is uniquely well suited for multi-metal deposition, as demonstrated by cold spray and explosion welding (two industrial techniques famed for their multi-metal capabilities and based on the same bonding principle). In contrast, it is believed that all existing small-scale AM methods face significant challenges in this area. There are inhibiting, fundamental challenges with all existing multi-material technology. In summary, the primary concerns with the state of the art are based on inferior materials' performance due to⁵ (colloidal inks, LIFT of melts, inorganic materials by TPL through pyrolysis) or contamination⁵ (FEBID); or a limited range of materials' combinations (challenging co-sintering of colloidal inks; electrochemical methods are primarily limited to metals; coating or filling of TPL templates is not site-specific); or extreme scale-up challenges (FEBID).

For example, a first voxel and a second voxel (e.g., thin disks) may be microfabricated on a substrate, where the material of the first voxel and the second voxel are different. Following this, the first voxel may be accelerated toward a substrate by a laser, where the laser induces bonding of the first voxel to the substrate. Following this, the second voxel may then be accelerated toward the substrate by a laser, inducing bonding of the second voxel to the first voxel. This may be a generic method for creating heterostructured composite materials via additive manufacturing, e.g., with high resolution.

It is expected that the methods described herein will be key for upcoming commercial endeavors that will attempt to utilize the advantages of impact-induced bonding for microscale AM for a wide range of applications.

Certain embodiments using the unique solid-state bonding principle will be of great advantage for the following commercial applications:

Integrated manufacturing of permanent magnets for high-performance MEMS energy harvesters and other electromagnetic devices. Here, high-quality magnets hundreds of micrometers in size are needed for high-power devices (mW-W) that convert vibrations or wind and fluid flow to electric energy. Their fabrication is currently a major bottleneck¹⁹ (PVD and electroplating are limited to smaller dimensions). Because of a lack of high-quality alternatives, bulk rare-earth magnets are often manually placed—a fabrication route that is not conducive to the economic manufacturing of devices with tight specifications. Certain of the embodiments described herein could serve as a fabrication tool compatible with standard MEMS processes and could pave a way to high-throughput, integrated fabrication of high-quality micro-magnets. One can envision assembling magnets from sputter-deposited, textured NdFeB thin films. Because currently no technology for the integrated manufacturing of magnets of the required size exist, commercialization can already be successful by providing magnets with a performance close to bulk rare earth magnets. Recent cold-spray deposition of composite NbFeB magnets²⁰ has already shown the same remanence magnetization as CoPt (the state of the art in microfabrication of magnets tens of μm thick—CoPt has only half the energy product of NbFeB). It is believed that certain of the embodiments described herein should be able to perform significantly better because, in contrast to cold spray, embodiments described herein can reduce the amount of binder and introduce texture, two simple strategies which result in higher strength of magnets.

Fabrication of high-strength microstructures for medical devices and minimally-invasive surgery tools. It is believed that no existing technologies can offer AM of hard, medical-grade alloys. The concepts described herein can work directly with already-approved metal powders and ensures high mechanical strength through the impact-induced hardening and the high density of deposited materials.

Repair of printed circuit boards. Currently this is a commercial application for the LIFT technology, transferring molten metal. It is expected that the conductivity of metals printed with the technology described herein will outperform that of LIFT.

It is believed that AM will develop toward higher resolution and multi-material capability for the manufacturing of materials with locally tailored composition and microstructure (although this is at the moment still an academic topic). It is believed that the embodiments described herein are uniquely well suited to explore a future market due to its anticipated major advantages over competing principles when it comes to multi-metal deposition and the deposition of metal-matrix composites (for cermets, fuel cell electrodes, heterostructured magnets or thermoelectric materials)

Competing technology to small-scale AM, LIGA (Lithography, Electroplating, and Molding), is a highly precise microfabrication technique used to create intricate structures on a micron and sub-micron scale. Currently the standard in microfabrication of 3D structures of complex geometry in metals. LIGA combines the principles of X-ray lithography, electroplating, and molding to achieve remarkable capabilities in the production of microdevices and components. It enables the creation of high-aspect-ratio structures with exceptional precision and repeatability. This technique is particularly valuable in the manufacturing of microelectromechanical systems (MEMS), microfluidic devices, sensors, and other miniaturized components. What it is missing: multi-material capability, which would be extremely difficult to add with any significant complexity. Further, it is based on electrodeposition, which fails to be applicable for the deposition of permanent magnets (due to internal stresses in these materials). In general, it is limited to the capabilities of electroplating.

The following examples are intended to illustrate certain embodiments of the present invention, but do not exemplify the full scope of the invention.

### Example 1

The following example generally describe different launch pad architectures from which a voxel may be accelerated.

Launch pad layers were systematically considered. Three guidelines for the launch pad were determined to be desirable: launch pad that can tolerate higher experiment temperatures, that guarantees an impact precision better than the particle diameter, and that allows the microfabrication of projectiles would improve the additive manufacturing process. First, previously used elastomers used in the standard launch pad naturally prevent heating of particles and targets to temperatures above approximately 100° C. Thus, inorganic materials are desirable for high-temperature experiments, e.g., using high power lasers to ablate a sacrificial layer.

Second, it is further desirable to use substrates standard in microfabrication for the target-facing side of the launch pad. This approach guarantees compatibility with cleanroom processes and thus versatility in the fabrication of projectiles by established microfabrication routes. For that, most importantly, the launch pad's surface must be chemically inert and flat. Neither condition is met by the established design using a polymeric film in contact with the voxel. The organic polymer film is incompatible with most harsh procedures for removal of organic contamination or stripping of photoresists. Further, the edge bead that originates from spin coating the high-viscosity polymer mixture interferes with structuring processes on top of this layer, such as direct write lithography or meniscus-guided template-assisted self assembly methods.

Third, it is desirable to us launch layers that minimize expansion upon launch. The simplest measure to improve spatial resolution of particle impact is a significant reduction of the flight distance of particles, that is, a reduction of the spacing of launch pad and target to a few tens of micrometers. This improvement is not accessible to standard launch pads, because the expanding polymer layer requires a spacing of several hundred micrometers (the elongation can be more than 400 μm at highest laser powers used). Consequently, minimization of the expansion of the launch pad is desirable.

Following these three guidelines, rigid layers in place of the standard elastomers were considered and a number of different materials, assembly methodologies, as well as thicknesses and sequences of layers were explored. FIG. 2B presents an overview of a launch pad that follows the above design guidelines. The core design elements of the new launch pad are stiff front (particle-facing) and back (laser-facing) glass layers (100-210 μm thick) that sandwich a chromium thin film as an ablation layer. The glass slides are joined with an adhesive. Crucially, this new design replaces the established compliant, thin polymer layer with a thick, stiff glass layer. One advantage of this design is the fact that standard glass substrates are flat and thus create a parallel and flat front and back surface of the launch pad (FIG. 2B). In addition, the materials used are standard materials in microfabrication with high chemical resistance, and the glass front surface is stable over long times (the performance of PU launch pads degrades with time) and can tolerate much higher temperatures. Finally, the much increased stiffness of the launch layer results in minimal expansion upon laser ablation, yet projectiles can still be launched at high speeds.

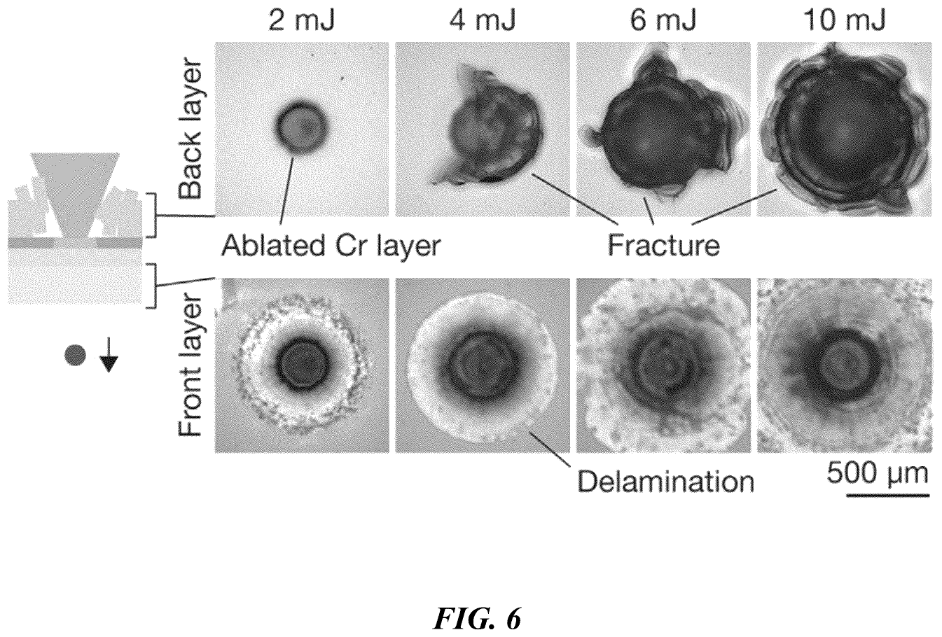

Because of the rapid plasma expansion upon laser interaction with the chromium layer, there is a large volume change that must be accommodated. Without the soft polymer layer to provide that accommodation, the rigid glass structure is prone to fracture instead (FIG. 6). Yet, it is found that such fracture can be directed to the back glass layer with appropriate design. Failure invariably occurred in the glass slide adjacent to the chromium layer (i.e., the glass that was coated with chromium). Thus, it is important that this glass is facing the laser beam, not the target, as sketched in FIG. 6. With this architecture, fracture of the front glass is avoided for all the different launch stacks used in this study at most tested laser powers, and projectiles are launched without debris impacting the target (fracture of the front glass was observed for thinnest glasses and highest laser powers). Failure of the back glass typically occurred at pulse energies >2 mJ, that is, at energies much lower than those that enable maximum particle velocities—fracture of the back glass is thus not obviously a limiting factor for particle velocity. Notably, redirection of the laser damage to the rear of the launch pad, affecting parts of the launch pad that are not directly involved in particle launch, could permit future designs that enable higher particle velocities. Specifically, with this approach, the maximum laser power that can be used, and thus the maximal initial pressure that can be generated, are not so directly limited by the strength of materials that ought to contain this pressure. In contrast, with the standard launch pad using an elastomeric polymer, the maximum laser power is limited by the toughness of the polymer layer—at too high laser powers, the polymer fails and the target is exposed to ablated debris.

In general, roughly the same degree of launch pad damage in both glass and PU launch pads when compared at the same particle velocities (instead of laser energies) was achieved. While consumed or damaged launch pad area per launch event is generally not of importance for standard laser-induced particle impact testing (LIPIT) experiments, it could become of practical interest for high-throughput experiments that demand a high number of shots per launch pad. Note that in this study, the traditionally-used gold layer was replaced with chromium, also for PU launch pads. The use of chromium was motivated by the observation that the damage mode in PU launch pads changes with adhesion strength of the metal film to glass. With gold, damage is caused by delamination of the gold film by the expanding PU bubble. Chromium avoids delamination thanks to its better adhesion to glass. Thus, the area of launch pad affected by a single particle launch is reduced, even though the same particle velocities are achieved.

A common concern in laser-driven launch of projectiles is shielding of the projectile from the ablation laser pulse and the heat of the ablation event. In the new launch pad, the thickness of the employed glass layers is sufficient for thermal shielding before launch. In particular, for borosilicate glass with a thermal diffusivity of approximately D≈4×10-3 cm² s⁻¹ (approximately a factor four higher than that of PU), even in 1 s the thermal diffusion length is only d≈500 nm (compare with the glass thickness of 100-200 μm). Consistent with this, epoxy heat shields 3.5 μm thick have been argued to provide sufficient thermal protection in shock-assisted launch scenarios. Additionally, the new launch stack could accommodate a second metal layer (as previously used for laser-launched flyer plates) or nontransparent front glass as light shields if required.

In LIPIT experiments, small and often unavoidable variations in take-off angles between individual shots result in a variance of flight paths. Potential causes of this variability include errors in particle alignment relative to the laser focal spot, local inhomogeneities of the launch pad or the particle shape, or the adhesion of particle to substrate. For purely geometrical reasons, the lateral divergence between individual paths increases with flight distance. Thus, the simplest measure to increase spatial impact resolution on the target is to decrease the spacing between launch pad and target.

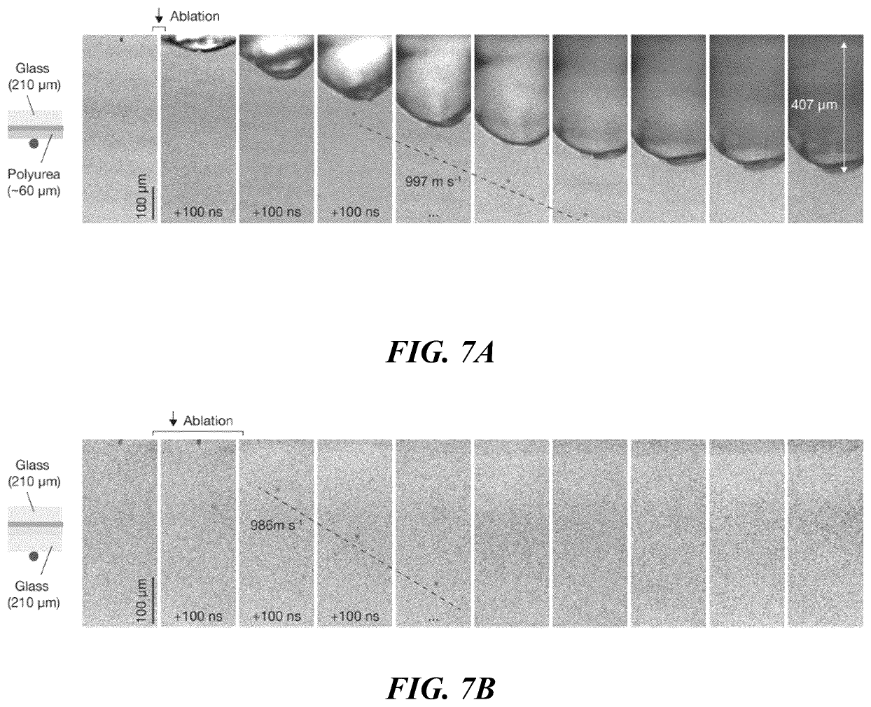

With previous launch pad designs, decrease of the flight distance is limited to ≈500 μm due to the severe deformation of the polymer balloon at the highest laser powers. The maximal extension of the elastomer layer upon ablation at high but typical energies of 12 mJ is ≈400 μm (FIG. 7A). In contrast, the expansion of the glass surface upon ablation at all tested laser powers is so minimal that it was not detected with high-speed microscopy (FIG. 7B). Consequently, the deformation of the launch pad surface no longer imposes a limit to its distance to the target-straightforward improvement of spatial impact resolution is thus unlocked.

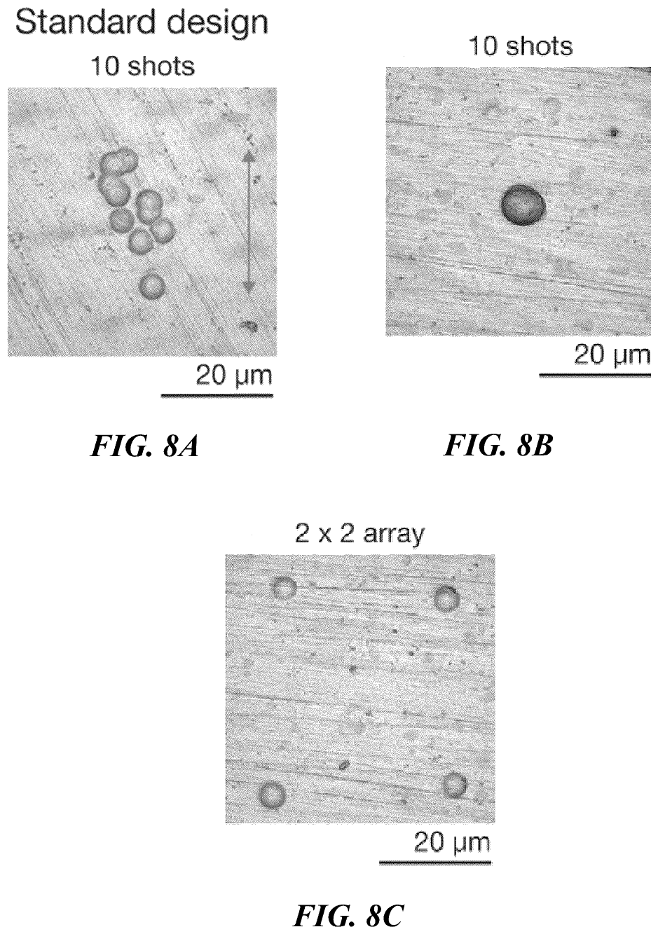

The precision of impact by indenting a polished aluminum target was measured with SiO₂ particles (7.38±0.24 μm in diameter as stated by the vendor) ten times without translation of the target between shots. An impact velocity of ≈200-250 m s⁻¹ is chosen so as to produce a reasonably small indentation, facilitating the identification of individual impact sites after the fact. FIG. 8A presents a typical indentation pattern produced from a standard PU launch pad using a spacing between launch pad and target of 500 μm. In this micrograph, the maximum spread of impact centers in horizontal and vertical directions is 10 and 23 μm, respectively. Notably, the larger variance in the vertical axis is an experimental artefact caused by the use of only one side-view imaging path to position particles before launch (standard in current LIPIT setups). This artefact has been eliminated in later experiments by using a second imaging path at an angle of 90° toward the first.

Reducing the distance of target to launch pad to only 50 μm uniquely facilitated with a low-expansion glass launch pad-immediately increases impact resolution to a value much smaller than typical particle diameters (FIG. 8B). The precision is increased to a level where the ten individual impacts are superimposed to form a single indentation. The maximum lateral error of impact locations was estimated to be ≈±1.75 μm, with a standard deviation that is likely smaller but can presently not be measured. The stated number is derived from a comparison of the approximate width of single indents formed at the same impact velocities, 4.5-4.8 μm (FIG. 8C), with the width of the crater in FIG. 8B, 8 μm (1.75 μm is half the distance between the centers of two circles 4.5 μm in diameter that fit in a circle 8 μm wide). In theory, a similar accuracy could be expected with the PU launch pad upon reduction of the spacing between launch pad and target to 50 μm (a reduction of distance by a factor ten should reduce the spread by a factor of ten, that is, to a value of ≈1 μm). In practice however, such a small spacing is only practical for the lowest particle velocities where the bubble expansion is minimal.

Importantly, a spacing between glass launch pad and target of 50 μm (and likely less) is still practical for everyday experiments. The results in FIG. 8B were obtained with a launch pad 25 mm in diameter and a target ≈0.5×1 mm in size. The parallelism of the target to the launch pad was manually adjusted with a simple goniometer, and the launch pad and target were translated with coarse, manual micrometer stages. Velocities higher than 2 km s-1 can likely be measured over a flight distance of only 20 μm with a frame rate of 109 Hz, as offered by contemporary multi-channel framing cameras. Finally, the challenge of illumination, which becomes more difficult with smaller gap sizes, can certainly be solved for gap distances of a few tens of micrometers using more careful alignment, brighter sources or smaller launch pads and targets. Thus, the spacing required for an impact resolution that is much smaller than the particle diameter can easily be managed with simple equipment, especially if one would consider larger particles than those used in this Example.

In conclusion, the new launch pad permits substantial shortening of the particle travel path, which in turn significantly reduces the spread caused by experimental variation in take-off angle. If needed, minimal flight distances can now be reduced to a few particle diameters if highest precision is needed. Importantly, it was observed at this stage, the limiting factor to reproducibility is particle alignment before launch. Improvements to the setup (more precise translation stages) and the alignment procedure are expected to push the resolution of impact to better than ±1 μm.

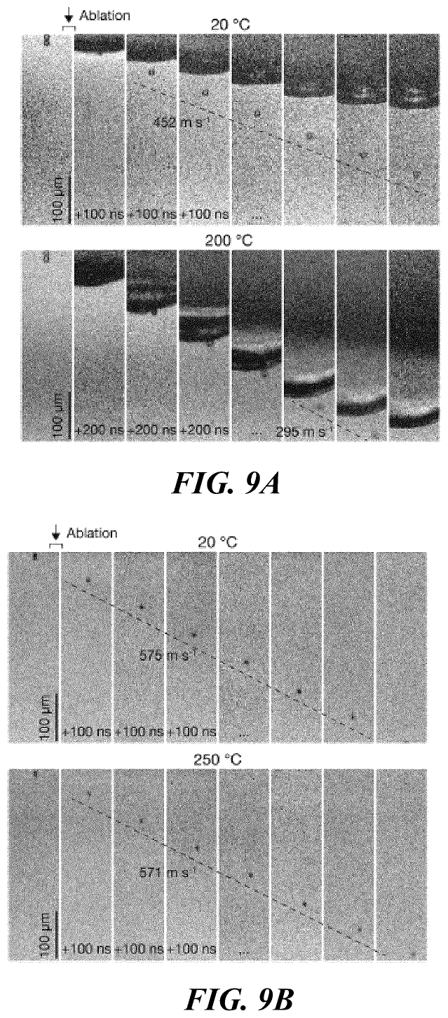

The highest temperature so far reported for LIPIT experiments is 91° C.; although the substrate is heated in such experiments, the very close (sub-mm) proximity of the launch pad achieves roughly comparable temperatures there as well. The onset of degradation of PU, that is, mass loss above 200° C., sets an upper temperature limit to its use. Already at lower temperatures, the pronounced decrease of the polymer's strength and stiffness with temperature severely affects particle launch (FIG. 9A). At 200° C., the PU balloon extends to approximately three times the distance observed at room temperature. In addition, a change in the shape of the balloon causes launch of the particle at an angle. In contrast, launch from glass launch pads is stable up to temperatures of 250° C. (FIG. 9B) and particles were successfully launched at 300° C. (that is, 100° C. above the onset temperature of degradation for PU). Here, a glass launch pad with a thick front (210 μm) and thin back glass (100 μm) was used to prevent fracture of the front glass at high temperatures and laser powers. With this launch pad, no change in launch behavior was observed up to 250° C. At 300° C. fracture of the launch pad was observed at particle speeds of 780 m s⁻¹, but no ejection of fragments that would cause contamination of the target was detected. The temperature-limiting component in the new design is the adhesive. The material used here is only rated for permanent operation at temperatures of 125° C. Correspondingly, a deterioration of its properties and resulting fracture of the particle-facing side of launch pads that show no signs of failure at room temperature were observed. The use of high temperature adhesives or purely inorganic bonding technologies (for example diffusion bonding) leads to a further extension of the temperature window.

Microfabrication of projectiles is a natural direction for LIPIT, as it permits more controlled evaluation of the role of impact geometry, and more reproducible impact conditions. Additionally, fabrication of ordered, addressable arrays of projectiles provides a significant advantage over the stochastic arrangement of particles in conventional LIPIT when it comes to high-throughput experiments. The new launch pads are compatible with most standard microfabrication processes with their flat, chemically inert surfaces for facile and versatile processing. As a demonstration of this capability, thin film metal disks were launched from the glass launch pads.

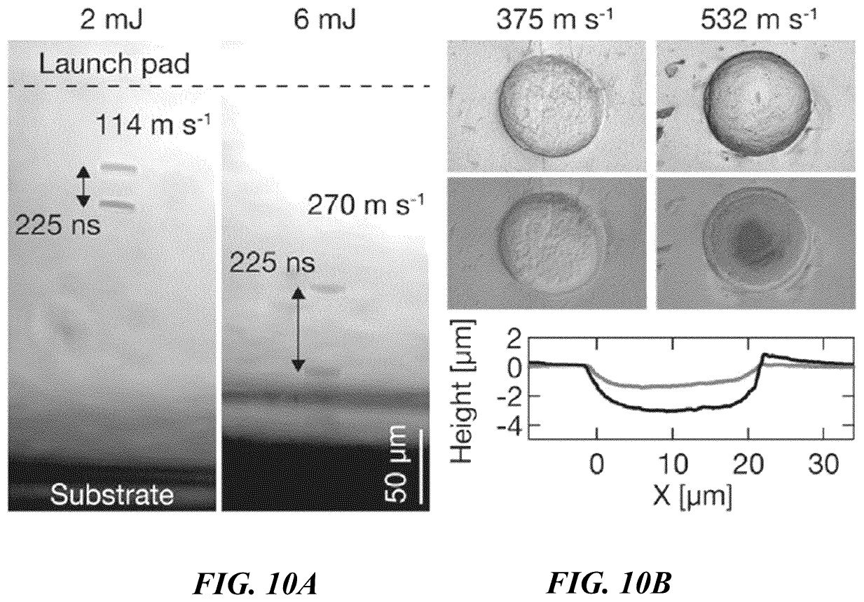

Arrays of 20 μm-wide gold disks 2-5 μm in height were fabricated by templated electroplating of gold in structured photoresists (FIG. 3). FIG. 10A demonstrates the launch of individual, intact disks at different velocities. Interestingly, the disks are launched with ease despite an underlying chromium adhesion layer which guarantees significant adhesion. Modification of the adhesion strength increases launch efficiency. The highest speeds achieved with these disks were ≈700 m s⁻¹ (16 mJ). In general, little rotation of the projectiles was observed for most shots. Roughly parallel impact is suggested by craters left in the aluminum target (FIG. 10B). Yet, disks often adapted a curved shape in flight (FIG. 10A, 6 mJ). Such bending of disks, or plasticity of the disks upon impact, could be the origin of the rounded corners of the indents left in the target. In general, the homogeneous launch is an additional advantage of the present launch pad design: parallel impact is achieved due to the parallel launch surface and the short flight path. With a PU launch pad, the loss of parallelism upon balloon inflation, combined with the long flight distance, are not conducive to achieving oriented impacts.

The present launch concept adds various capabilities over previous setups. For example, the front glass prevents any debris or hot gases generated upon ablation from interaction with the target (typically observed after launch of flyers by direct ablation), and modification of the launched disks is avoided as much as possible. Additionally, the size of disks launched here is significantly smaller than those typically used as flyer plates, opening the door to studies of sample size effects.

The maximum obtainable velocity of launched particles is a primary criterion of any launch pad for LIPIT. In contrast, launch efficiency (i.e., velocity/laser pulse energy) is of minor concern, as typical pulse energies are easily obtained with standard ns-laser systems. Yet, of course it is an indicator that should guide launch pad design to some extent (a higher launch efficiency typically results in a higher number of shots that can be obtained from a single launch pad for a given speed, because the area damaged by the ablation pulse scales with laser power). Overall, the new design offers competitive performance—both efficiency of launch and maximum speed are as high as or higher than those of the standard design (although, limits to the toughness or yield strength of particles can results in lower velocities).

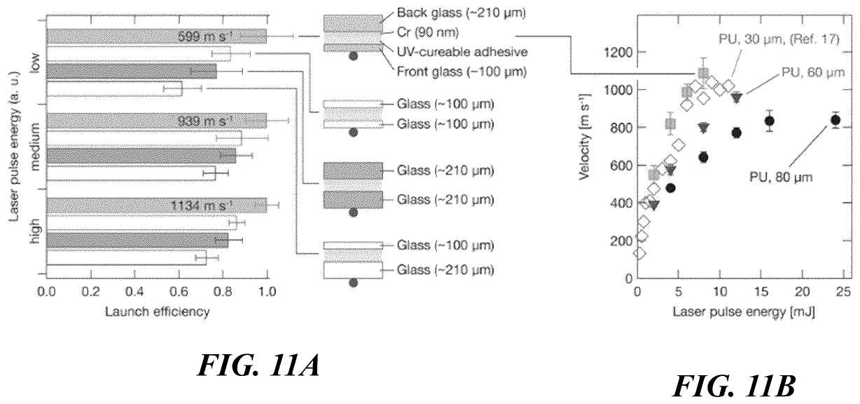

Different architectures of the launch stack were explored by varying the thickness of the front and back glass layers (FIG. 11A). Designs were evaluated based on launch velocities measured with SiO₂ particles 7.38±0.24 μm in diameter. From this comparison, two general trends emerged. For a given laser pulse energy, the launch velocity increases with 1) a thinner front glass and 2) a thicker back glass. With the most efficient design (backside glass: 210 μm, frontside glass: 100 μm), the measured velocities and launch efficiency are slightly higher than those reported in the literature using 30 μm-thick PU launch layers and significantly better than those achieved in this Example with conventional PU launch pads that use 60-80 μm thick PU layers (FIG. 7b). The highest velocity measured for a glass launch pad was 1134±42 m s⁻¹. Notably, it is believed that particle velocities are currently not limited by the new launch pad itself (i.e., the maximum impulse it can provide), but rather the toughness of particles. Further, metal particles plastically deform. Thus, ensuring integrity of projectiles is important during use. Nonetheless, from the data shown here, it can be inferred that two factors likely limit the maximum impulse from the launch pad. One limiting element is likely the amount of “fuel,” that is, the thickness of the metal layer. Optical analysis of launch pads that show a plateau in particle velocity (for example, designs with 210 μm-thick front and back glasses) shows that the area of ablated chromium stagnates at laser energies where plateauing of the particle velocities is observed. Consequently, an increase of the thickness of the metal layer may provide higher launch velocities for any given laser energy. Second, the thickness of the front glass seems to negatively affect maximum speeds. However, it is believed the thickness of the front glass mainly affects efficiency but not maximal velocity—with a thicker metal layer, higher velocities can probably be obtained also with thick front glasses.

In this Example, a new launch pad design for LIPIT that replaces the established, compliant polymer launch layer with a stiff, flat, and inert glass layer was presented. A first elemental design rule was established that maximizes particle launch velocities, namely a thin front layer combined with a thick back layer. This redesign offers a number of advantages over the standard launch pad: access to experimental temperatures of at least 300° C. under atmospheric conditions, and the potential to increase this limit with the use of more appropriate adhesives; a significantly improved spatial precision of impact enabled by the fact that reduction of particle flight distance is readily feasible with the new design for all particle velocities; compatibility with most microfabrication routines for patterning of projectiles; and the ability to launch non-spherical geometries, such as disks, without significant rotation. At the same time, the design achieves roughly the same launch velocities for typical 5-15 μm brittle particles.

These improvements facilitate new experimental programs in important directions for the field. First, elevated temperatures are required for, for example, the basic scientific understanding of thermally-activated deformation mechanisms and microstructure evolution at high strain rates, the study of substrate temperature and particle preheating in cold spray, or the investigation of hard-particle erosion in aerospace settings. Second, the improved precision of impact serves an immediate need in the community. With typical particle sizes in LIPIT of 10-50 μm, the demonstrated resolution <±2 μm immediately allows for systematic, efficient studies of particle-on-particle impacts. Additionally, this precision is an important step toward real-time optical spectroscopy of the impact, as it tackles the challenge of synchronization in space. For this kind of experiment, the impact site must coincide with the focal point of the stationary, optical probe. Third, the microfabrication of projectiles may foreshadow a new era of engineered impactors for LIPIT, optimized for the study of specific properties or physics, or whose arrangement into automatically addressable arrays facilitates high-throughput LIPIT experiments for the rapid exploration of materials behavior under high-rate dynamic conditions.

More broadly, these developments demonstrate how significantly changes in the launch pad design advances the experimental capabilities of LIPIT. Several of the design principles and elements here point to further possible progress for next-generation launch pad designs. At the same time, as illustrated by the challenges of the new design (most notably, plastic deformation of metal particles), no single launch architecture will likely satisfy all the experimental needs of the community.

### Experimental Section

Preparation of Launch Pads: In general, fabrication of launch pads included two steps. First, deposition of a thin metal layer on a glass substrate. Second, the addition of the layer that launched particles. For the traditional design, this included spin coating and curing of an elastomeric polymer layer. For the new design, a second glass slide was glued to the metal-coated surface of the first glass slide. A range of cover glasses of different thickness was used to fabricate launch pads: No. 2 (VWR, thickness: 170-250 μm), No. 1 (electron microscopy sciences, thickness: 130-170 μm), No. 0 (Gold Seal, Thermo Scientific, thickness: 85-120 μm). An overview of a final iterations of designs is given in Table 1.

TABLE 1
New launch pad architectures used in Example 1.

| Label | Back Glass (microns) | Front Glass (microns) | Cr layer (nm) |
|---|---|---|---|
| 210/210 | 170-250 | 170-250 | 90 |
| 210/100 | 170-250 | 85-120 | 90 |
| 100/100 | 85-120 | 85-120 | 90 |

Chromium layers 90 nm in thickness were RF sputter deposited (Orion 5, AJA) using the following parameters: ≤2.5×10⁻⁵ Torr base pressure, 3 mTorr deposition pressure, 1 Å s⁻¹ deposition rate (as verified by a quartz crystal microbalance before and after deposition). Prior to deposition, substrates were sonicated in DI water, followed by a plasma cleaning step (0.15 mbar oxygen, 15 min, Nano, Thierry). In addition, substrates were plasma-treated inside the sputter chamber immediately prior to deposition (3 mTorr Ar, ≈15 W). Gold layers (90 nm thick) were deposited using a small laboratory sputter coater (SC7640 sputter coater, Quorum Technologies) without prior cleaning of the glass substrates. Polyurea precursors (Modified MDI Isocyanate curative, RCS Rocket Motor Components, and Versalink P-650, Evonik) were mixed in a planetary centrifugal mixer (2 min, ARE-310, Thinky) and then spincoated (G3P-8, Cookson Electronic Equipment) at 750 rpm for 5 min. After storage under low vacuum for 24 h, the PU films were cured at 85° C. for 18 h. For the new launch pad design, front glass slides were glued to Cr-coated glass slides using a UV-curable adhesive (NOA 61, Norland Products). First, Cr-coated slides and bare glass slides were plasma cleaned (air, PDC-32G, Harrick). Then, L of adhesive was pipetted on the Cr-coated slide and the front glass slide was added on top without application of pressure. After waiting a few minutes for the adhesive to be drawn out toward the edges of glass slides, the sandwich was cured with ≈10 mW cm-2 (λ=320-390 nm, measured with a UV intensity meter, ACCU-CAL-50, Dymax Corporation) to an energy of ≈3 J cm⁻². Subsequently, the bond was aged at 50° C. for ≈15 h. The thickness of the adhesive layer measured for one launch pad was ≈20 μm and essentially homogeneous across the launch pad (measured in the center and 5 mm toward the edge). For some launch pads, an epoxy resin (Double/bubble green, Hardmann) was used as an adhesive.

Microfabrication of Gold Disks: A gold seed layer (50 nm) with a chromium adhesion layer (10 nm) was sputter-coated (Orion 5, AJA, ≤2.5×10⁻⁵ Torr base pressure, 3 mTorr deposition pressure, 1 Å s-1 deposition rate, RF deposition) on plasma-cleaned glass substrates. On top of this coating, photoresist (AZ 10XT, MicroChemicals) was spin coated to a thickness of ≈7 μm (500 rpm (3 s), 1000 rpm (3 s), 3000 rpm, (60 s)) and soft-baked (110° C., 120 s). A pattern of 20 μm-wide disks (typical array spacing 500 μm) was exposed in a direct-write laser system (MLA 150, Heidelberg, exposure mode: standard, laser: 405, dose: 425, defocus: 0) and subsequently developed (2 min 45 s, AZ435 MIF, MicroChemicals).

Gold films 2-5 μm in thickness were deposited into the photoresist mask (typical area 0.252 cm2) by pulsed electrodeposition in an in-house designed two-electrode cell (platinum-mesh counter electrode, power supply: DUPR10-1-3 XR, Dynatronix) using parameters recommended by the supplier of the gold plating bath (TSG-250, Transene Company) (4.3 mA cm⁻² peak current density, 10 ms ON, 10 ms OFF, forward only, 60° C., stirring 300 rpm).

After plating, the resist was plasma etched (0.15 mbar oxygen, 60 min, Nano, Thierry) and subsequently, the gold seed layer wet-etched.

LIPIT: Detailed descriptions of the in-house-designed LIPIT setup have been published earlier.[12,16,17] In brief, LIPIT experiments were conducted using an all-optical platform. An intense laser pulse (pulsed Nd:YAG, pulse width 10 ns, λ=532 nm) was focused onto the launch pad (30-mm focal length lens with a minimal focal spot size of 5 μm). Upon ablation of the metal film, microparticles were accelerated and launched from the launch pad. The particle speed was controlled by adjusting the laser energy between typically 10 and 240 mJ. In general, optimization of launch velocity (adjusting distance between focus lens and launch pad to optimize the size of the ablated area as well as optimizing lateral alignment of the particles to the laser beam) was performed prior to experiments for each of the different launch pad designs. For reproducible impact location, reproducible alignment of particles in the center of the ablation laser beam was crucial. In previous versions of the system, a single imaging path was used for this task. For this Example, a second imaging path perpendicular to the first was added to render particle alignment more accurate.

Two high-speed imaging systems were used. Most experiments were performed with a high-speed camera (SIMX16, Specialised Imaging), with a typical frame and interframe time of 5 and 95-195 ns, respectively. A 10 S laser pulse (λ=640 nm) was used for illumination of 16 frames. The launch of gold disks was observed with an alternative setup. Here, two imaging laser pulses were produced by splitting the output of a dye laser (pumped with a fraction of the ablation laser pulse) in two and delaying one of the pulses by 225 ns by running it through a delay line. Both imaging pulses were captured on a single CCD camera (ORCAFusion, Hamamatsu). In general, all cameras were calibrated with resolution targets before experiments.

Particle velocities were evaluated using SiO2 particles (micro particles GmbH, with nominal diameters of 7.38±0.24 μm and 13.79±0.59 μm). Velocities were measured between consistent frame numbers for a given velocity. Reported velocity data points were averaged velocities of at least three shots each from two different samples (hence a minimum of six measurements per data point). 304 stainless steel particles were purchased from Cospheric. The size of individual steel particles was measured before launch.

Experiments at Elevated Temperatures: To assess the effect of increased temperatures on the performance of the launch pads, a heating stage (heated area≈1×2 cm in size) was positioned 1 mm below the launch pad. The ablated area was centered above the heating stage. The surface temperature of the heating stage was probed with a thermocouple. The temperature of the launch pads was not measured, but due to convection and the geometric factors (heated area much wider than the gap size) can be assumed to be similar to the substrate temperature. Upon change of the temperature, the heating stage with the launch pad in position was held at the set value for 5 min for equilibration before experiments.

Microscopy and Analysis of Layer Thicknesses: Optical microscopy of impact sites and damage in launch pads was performed with a laser scanning confocal microscope (VK-X250, Keyence). The same microscope was used to measure thicknesses of cured PU layers and the thickness of microfabricated gold disks. SEM was performed with a Gemini 450 instrument from Zeiss.

### Example 2

The following example generally describes a system and method of additive manufacturing.

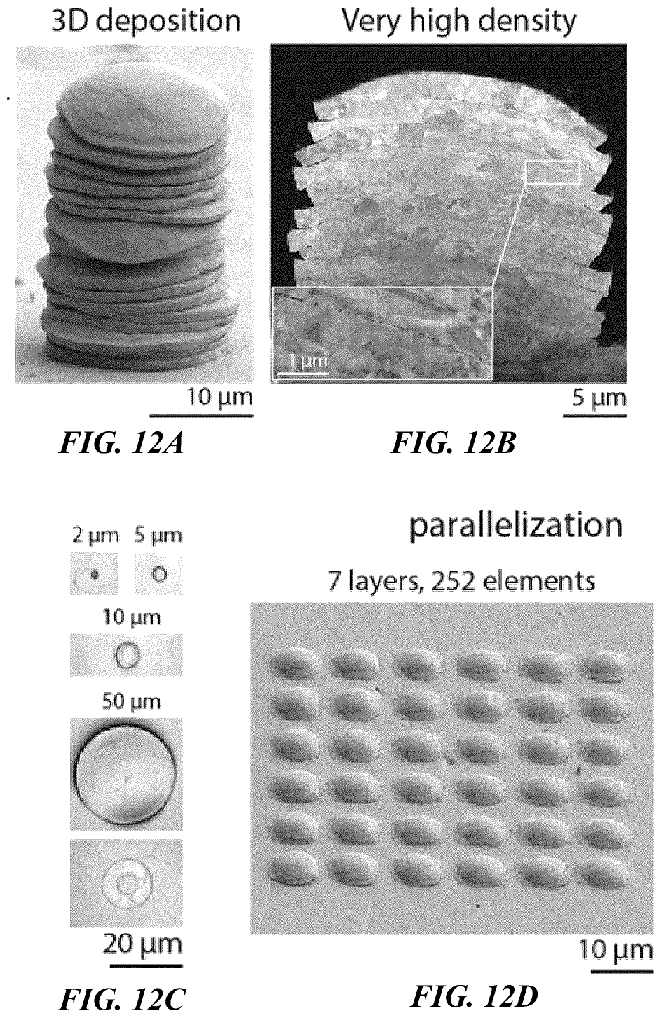

Thin film voxels were launched as described in Example 1 (FIGS. 2B-2C). The launching process was repeated to stack multiple Au voxels to form a stack as shown in FIG. 12A, demonstrating the ability to utilize the system for additive manufacturing. The deposited Au forms an almost fully dense structure as shown in FIG. 12B, and having a lower porosity than metals deposited by many other microscale additive manufacturing techniques. This shows the bond between voxels can be of low porosity. FIG. 12C shows various voxels that were microfabricated. Such voxels can be used to form structures with multiple voxels having high dimensional accuracy (e.g., less than or equal to 2 μm, or less) and/or complex shapes (e.g., microfabricated ring in FIG. 12C). Finally, the method was used to launch a 6×6 array of voxels in parallel. Seven layers of the 6×6 array of voxels were sequentially launched to form the structure shown in FIG. 12D.

It should be understood that the subject matter defined in the appended claims is not necessarily limited to the specific implementations described above. The specific implementations described above are disclosed as examples only. While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

### REFERENCES

[1] Hassani-Gangaraj, M., Veysset, D., Nelson, K. A. & Schuh, ChristopherA. A. In-situ observations of single micro-particle impact bonding. Scr Mater 145, 9-13 (2018).
[2] Lee, J.-H. et al. High strain rate deformation of layered nanocomposites. Nat Commun 3, 1164 (2012).
[3] Reiser, A. & Schuh, C. A. Microparticle Impact Testing at High Precision, Higher Temperatures, and with Lithographically Patterned Projectiles. Small Methods 7, 2201028 (2023).
[5] Reiser, A. et al. Metals by Micro-Scale Additive Manufacturing: Comparison of Microstructure and Mechanical Properties. Adv Funct Mater 30, 1910491 (2020).
[6] Hirt, L. et al. Additive Manufacturing of Metal Structures at the Micrometer Scale. Advanced Materials 29, 1604211 (2017).
[7] Ahn, B. Y. et al. Omnidirectional Printing of Flexible, Stretchable, and Spanning Silver Microelectrodes. Science (1979) 323, 1590-1593 (2009).
[8] Onses, M. S., Sutanto, E., Ferreira, P. M., Alleyne, A. G. & Rogers, J. A. Mechanisms, Capabilities, and Applications of High-Resolution Electrohydrodynamic Jet Printing. Small 11, 4237-4266 (2015).
[9] Serra, P. & Piqué, A. Laser-Induced Forward Transfer: Fundamentals and Applications. Adv Mater Technol 1800099, 1800099 (2018).
[10] Utke, I., Hoffmann, P. & Melngailis, J. Gas-assisted focused electron beam and ion beam processing and fabrication. Journal of Vacuum Science & Technology B: Microelectronics and Nanometer Structures 26, 1197 (2008).
[11] Hengsteler, J., Lau, G. P. S., Zambelli, T. & Momotenko, D. Electrochemical 3D micro- and nanoprinting: Current state and future perspective. Electrochemical Science Advances 2, 1-14 (2022).
[12] Hirt, L. et al. Template-Free 3D Microprinting of Metals Using a Force-Controlled Nanopipette for Layer-by-Layer Electrodeposition. Advanced Materials 28, 2311-2315 (2016).
[13] Reiser, A. et al. Multi-metal electrohydrodynamic redox 3D printing at the submicron scale. Nat Commun 10, 1853 (2019).
[14] Reiser, A., Schuster, R. & Spolenak, R. Nanoscale electrochemical 3D deposition of cobalt with nanosecond voltage pulses in an STM. Nanoscale 14, 5579-5588 (2022).
[15] Aarts, M., Reiser, A., Spolenak, R. & Alarcon-Llado, E. Confined pulsed diffuse layer charging for nanoscale electrodeposition with an STM. Nanoscale Adv 4, 1182-1190 (2022).
[16] Nydegger, M. et al. Additive manufacturing of Zn with submicron resolution and its conversion into Zn/ZnO core-shell structures. Nanoscale (2022) doi:10.1039/D2NR04549D.
[17] Porenta, N. et al. Micron-scale additive manufacturing of binary and ternary alloys by electrohydrodynamic redox 3D printing. ChemRxiv (2023) doi:10.26434/chemrxiv-2023-21vzq.
[18] Menétrey, M. et al. Targeted Additive Micromodulation of Grain Size in Nanocrystalline Copper Nanostructures by Electrohydrodynamic Redox 3D Printing. Small 2205302 (2022) doi:10.1002/smll.202205302.
[19] Dempsey, N. M. Hard Magnetic Materials for MEMS Applications. in Nanoscale Magnetic Materials and Applications 661-683 (Springer US, 2009). doi:10.1007/978-0-387-85600-1-22.
[20] Lamarre, J.-M. & Bernier, F. Permanent Magnets Produced by Cold Spray Additive Manufacturing for Electric Engines. Journal of Thermal Spray Technology 28, 1709-1717 (2019).

1. A method of additive manufacturing, comprising:
a. providing a substrate;
b. providing a first voxel and a second voxel;
c. accelerating the first voxel into the substrate to induce bonding of the first voxel to the substrate; and
d. accelerating the second voxel toward the substrate to induce bonding of the second voxel to the first voxel.

2. A method comprising
a. providing a substrate;
b. providing a microparticle or microfabricated thin film (a voxel); and
c. accelerating the voxel into the substrate to induce solid-state bonding of the voxel to the substrate.

3. The method of claim 1, wherein neither the voxel nor the substrate is heated by a laser.

4. The method of claim 1, further comprising shaping the first voxel prior to accelerating the first voxel into the substrate.

5. The method of claim 1, wherein the substrate comprises an inorganic material.

6. The method of claim 1, wherein the substrate comprises glass.

7. The method of claim 1, wherein the voxel comprises an inorganic material.

8. The method of claim 1, wherein the voxel comprises a metal.

9. The method of claim 1, wherein the voxel comprises gold metal (Au).

10. The method of claim 2, wherein c is repeated to stack the voxels and produce a 3D structure.

11. The method of claim 1, wherein a metal coating is produced on the substrate.

12. The method of claim 1, wherein a metal coating having a thickness of greater than or equal to 10 nm is produced on the substrate.

13. The method of claim 12, wherein the thickness of the metal coating is less than or equal to 10 microns.

14. The method of claim 1, wherein greater than or equal to 6 voxels are stacked on the substrate.

15. The method of claim 2, wherein a stack having a volume of greater than or equal to 1 mm³ is produced on the substrate.

16. The method of claim 1, wherein providing the first voxel and the second voxel occurs before accelerating the first voxel or the second voxel.

17. The method of claim 2, wherein providing the microparticle or microfabricated thin film occurs before accelerating the microparticle or microfabricated thin film.

18. The method of claim 1, wherein the accelerating causes an impact to induce solid-state bonding between the voxel and the substrate.

19. The method of claim 1, wherein the first voxel and the second voxel are sequentially transferred to the substrate.

20. A method comprising
a. providing a substrate;
b. providing a thin film; and
c. accelerating the thin film toward the substrate to induce bonding of the thin film to the substrate.

21-33. (canceled)
